(19) United States
(12) Patent Application Publication
(10) Pub. No.: US 2019/0035688 A1
(43) Pub. Date: Jan. 31, 2019

(54) METHOD OF BATCH TRANSFERRING MICRO SEMICONDUCTOR STRUCTURES

(71) Applicant: ULTRA DISPLAY TECHNOLOGY CORP., Taipei City (TW)

(72) Inventor: Hsien-Te CHEN, Taipei City (TW)

(21) Appl. No.: 16/045,072

(22) Filed: Jul. 25, 2018

(30) Foreign Application Priority Data
Jul. 26, 2017 (TW) 106125031

(51) Int. Cl. H01L 21/78; H01L 21/56; H01L 21/683

(52) U.S. Cl. CPC H01L 21/7813; H01L 2221/68368; H01L 21/6835; H01L 21/561

(57) ABSTRACT

A method of batch transferring micro semiconductor structures is provided. The method utilizes the selective laser lift-off (selective LLO) technology, and the micro semiconductor structures are selected in batch during the selective LLO process. Thus, the following transferring step does not need to prepare the concave patterns in advance, thereby avoiding the technical difficult derived by the micro-contact printing process.

### CROSS REFERENCE TO RELATED APPLICATIONS

This Non-provisional application claims priority under 35 U.S.C. § 119(a) on Patent Application No(s). 106125031 filed in Taiwan, Republic of China on Jul. 26, 2017, the entire contents of which are hereby incorporated by reference.

### BACKGROUND

### Technology Field

The present disclosure relates to a manufacturing process of the micro semiconductor structure and, in particular, to a manufacturing process of batch transferring micro semiconductor structures.

### Description of Related Art

In some researches, it is found that the lifetime, energy consumption, viewing angle and resolution of micro LEDs are superior to those of flexible AMOLEDs, so that the micro LEDs have advantages in the market. However, in practice, the micro LEDs may have some technical limitations such as the circuit drive designs, LED uniformity, transferring for huge amount of workpieces.

In the conventional manufacturing process of LED (having a length over 100 micrometers), a plurality of individually independent and arrayed LED dies are manufactured by a series processes (e.g. half cutting (electrical insulation), testing, and full cutting) after the epitaxial process. Then, a pick-up head is used to select and transfer the LED dies one by one to a carrier substrate. However, in the micronization of LEDs, the conventional process may encounter several difficulties. For example, the edge length of the micro LED die is relatively smaller (e.g. 100 micron or less), so the pick-up head, which has limitation in scale minimization, cannot effectively pick up the micro LED dies. For another example, the micronization of the die size means that the number of LED dies fabricated by the same sized wafer can be greatly increased. Unfortunately, the conventional process of picking and transferring the LED dies one by one cannot meet the needs of huge amount of manufactured LED dies and will result in a very low yield.

In the industry, the micro contact printing technology has been applied to form a huge number of concave patterns on the polymer material plate for correspondingly picking the micro LED dies. This method can achieve the requirement of transferring a huge number of micro LED dies. However, in practice, since the size of the micro LED dies is very small, the interval between two adjacent concaves (or convex parts) on the polymer material plate cannot be easily controlled. In particular, even if the convex parts can precisely align and pick up the target dies to be transferred, the polymer material plate may still have a high risk to be deformed and to simultaneously pick up the other dies next to the target dies while the hardness and adhesiveness of the polymer material is not precisely controlled.

Therefore, it is desired to develop a more flexible manufacturing process.

### SUMMARY

In view of the foregoing, the present disclosure is to provide a method of batch transferring micro semiconductor structures, which can transfer a batch of or a huge amount of micro semiconductor structures and can be widely applied to the art of transferring various micro semiconductor structures in batch or in a huge amount.

In view of the foregoing, the present disclosure is to provide a method of batch transferring micro semiconductor structures, which can select the micro semiconductor structures by laser lift-off (LLO) for transferring the micro semiconductor structures in batch or in a huge amount.

To achieve the above, the present disclosure provides a method of batch transferring micro semiconductor structures, which comprises the following steps:

attaching an adhesive material on a semiconductor device, wherein the semiconductor device comprises a native substrate and array-type micro semiconductor structures grown on the native substrate, and the array-type micro semiconductor structures define a plurality of micro semiconductor structures arranged in an array;

selectively lifting a part of the array-type micro semiconductor structures off the native substrate, so that a batch of the selected array-type semiconductor structures is remained on the adhesive material after the native substrate is removed; and

providing an attaching device for transferring the batch of the selected array-type micro semiconductor structures to a target substrate.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1A is a flow chart of a method of batch transferring micro semiconductor structures according to a first embodiment of this disclosure;

FIG. 1B is a flow chart of a method of batch transferring micro semiconductor structures according to a second embodiment of this disclosure;

FIG. 1C is a flow chart of a method of batch transferring micro semiconductor structures according to a third embodiment of this disclosure;

FIGS. 2A to 2I are schematic diagrams showing the manufacturing process of FIG. 1A;

FIGS. 3A to 3G are schematic diagrams showing another manufacturing process of FIG. 1A;

FIGS. 4A to 4B are schematic diagrams showing still another manufacturing process of FIG. 1A;

FIG. 5 is a schematic diagram showing still yet manufacturing process of FIG. 1A;

FIGS. 6A to 6B are schematic diagrams showing a part of the manufacturing process of FIG. 1B; and

FIGS. 7A to 7B and FIGS. 8A to 8D are schematic diagrams showing the manufacturing process of FIG. 1C.

### DETAILED DESCRIPTION OF THE DISCLOSURE

The present disclosure will be apparent from the following detailed description, which proceeds with reference to the accompanying drawings, wherein the same references relate to the same elements.

A method of batch transferring micro semiconductor structures of this disclosure is used to pick up array-type micro-scaled structures/devices in batch and integrate them on to a non-native substrate without damaging the structures/devices. The present disclosure will be apparent from the following detailed description, which proceeds with reference to the accompanying drawings, wherein the same references relate to the same elements.

In the following, the terms “semiconductor structure” and “semiconductor device” are synonyms generally referring to a semiconductor material, die, structure, device, component of a device, or semi-finished product. The term “micro” of micro semiconductor structures and micro semiconductor devices generally refers to microscales. Semiconductor devices include high-quality monocrystalline semiconductors and polycrystalline semiconductors, semiconductor materials fabricated by high temperature processing, doped semiconductor materials, organic and inorganic semiconductors, and combinations of semiconductor materials and structures having one or more additional semiconductor components or non-semiconductor components (such as dielectric layers or materials, or conductive layers or materials). Semiconductor devices include, but are not limited to, transistors, photovoltaic devices including solar cells, diodes, light-emitting diodes, laser diodes, p-n junction diodes, photodiodes, integrated circuits, and sensors. In addition, a semiconductor device may refer to a component or portion of a functional semiconductor device or product.

In the following, the term “target substrate” refers to a non-native substrate for receiving the “micro semiconductor structures”. The material of the native substrate or non-native substrate includes polymers, plastics, resins, polyimide, polyethylene naphthalate, polyethylene terephthalate, metal, foil, glass, flexible glass, semiconductor, sapphire, thin film transistor (TFT), or the likes.

For ease of understanding and explanation, the “micro semiconductor structure” used herein is exemplified by a micro LED (light-emitting diode) die, or a semi-finished product of a plurality of micro semiconductor structures that has been formed with at least one epitaxial layer and has been defined. The “semiconductor device” includes a “micro semiconductor structure” and a wafer for growing a “micro semiconductor structure.” The “target substrate” as used herein is exemplified by a thin film transistor.

### First Embodiment

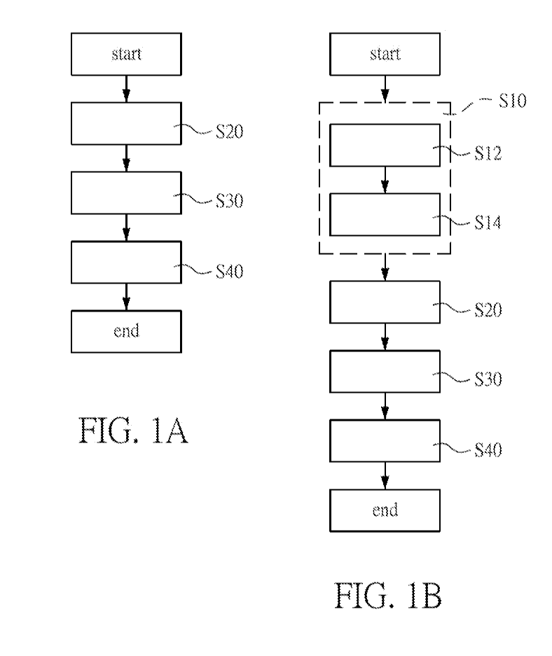

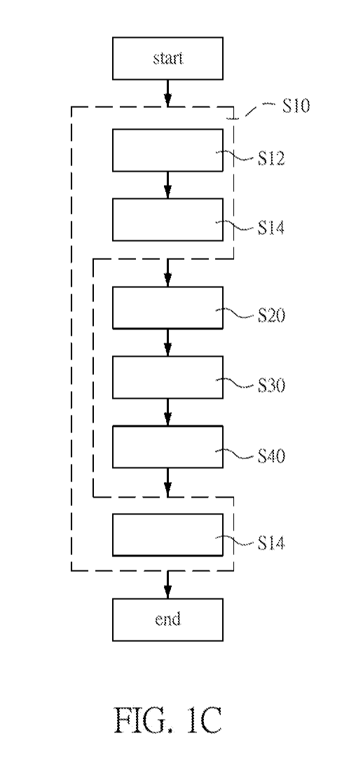

FIGS. 1A, 2A to 2I, 3A to 3G; and 6A to 6B are schematic diagrams showing the flow chart and most manufacturing process of the method of batch transferring micro semiconductor structures of this disclosure.

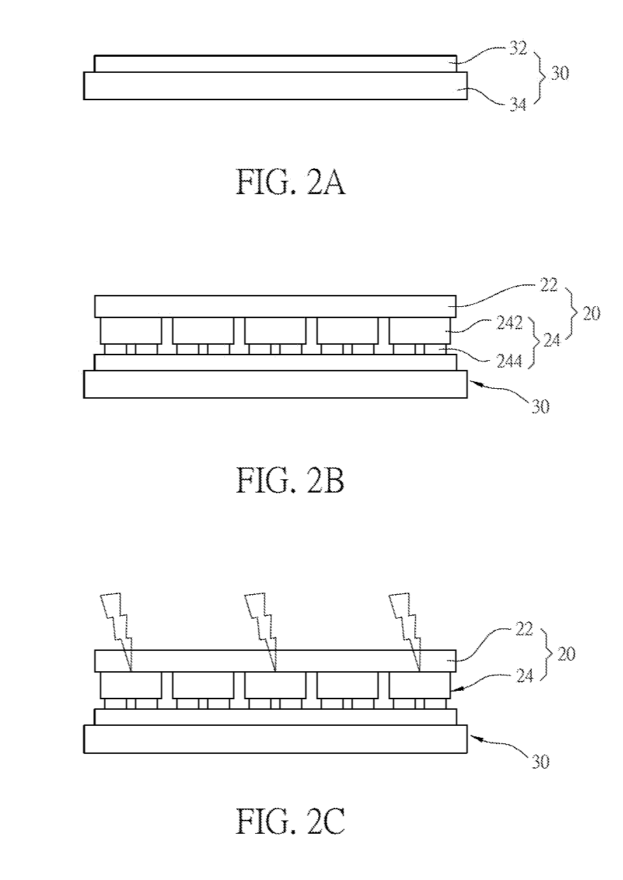

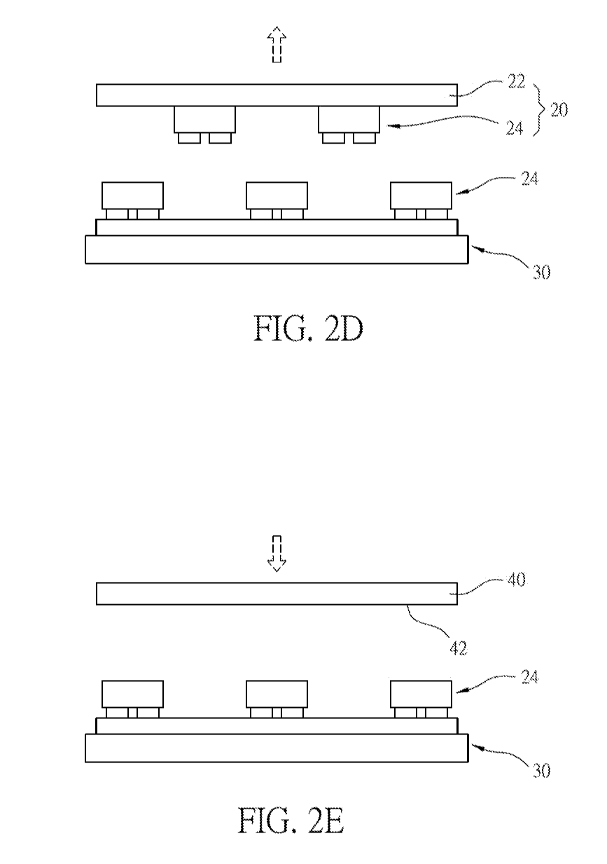

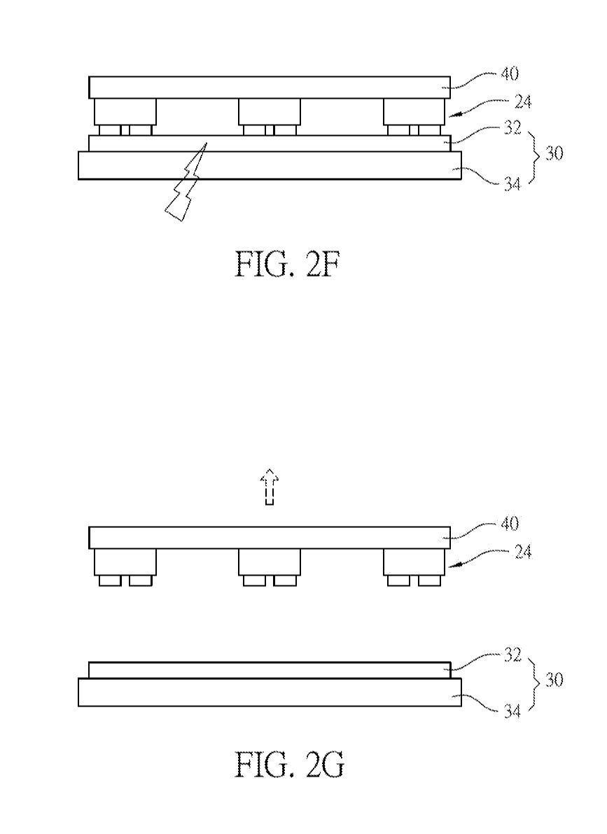

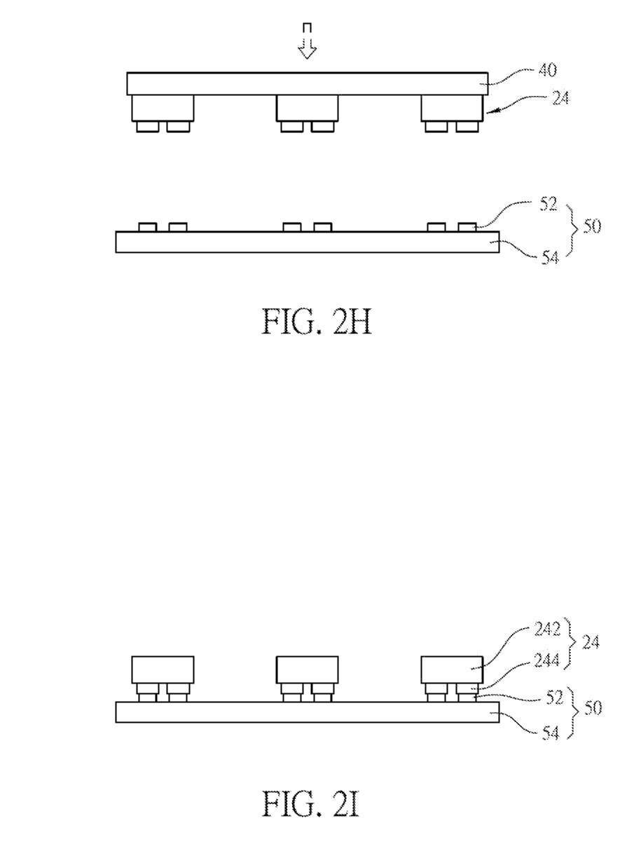

With reference to FIG. 2B, a semiconductor device 20 includes a native substrate 22 and array-type micro semiconductor structures 24 grown on the native substrate 22. The definition of the array-type micro semiconductor structures 24 is a plurality of micro semiconductor structures 24 arranged in an array. In addition, each semiconductor structure 24 includes at least one electrode 244. Alternatively, the array-type micro semiconductor structures 24 may include a plurality of individual micro LED dies fabricated by complete manufacturing processes.

As shown in FIG. 1A, the method of batch transferring micro semiconductor structures of this disclosure at least includes the following steps S30, S40 and S50.

Referring to FIGS. 2A and 2B, the step S20 is to attach an adhesive material 30 on a semiconductor device 20. To be noted, the adhesive material 30 of this embodiment can be different depending on various material properties, types of micro LEDs, or methods for removing the native substrate 22. In general, the adhesive material 30 comprises a base layer 34 and an adhesive layer 32 disposed on the base layer 34. The adhesive layer 32 can be a UV tape. The components and aspects of the adhesive material 30 disclosed in this embodiment are for illustrations only and are not to limit this disclosure.

Referring to FIG. 2C, the step S30 is to selectively lift a part of the array-type micro semiconductor structures 24 off the native substrate 22. In this embodiment, the part of the array-type micro semiconductor structures 24 are selectively lifted by laser lift-off (LLO) technology. In addition, a pattern of the selectively lifted array-type micro semiconductor structures 24 is usually corresponding to a pattern design on a target substrate 50 (see FIG. 21). In this embodiment, the batch selecting event happens in the laser lift-off step, so whether the concave pattern is formed on the attaching device 40 in advance or not does not affect the following batch transferring step. In other words, the concave pattern formed by the conventional micro contact printing technology can also be used in this disclosure and is not excluded. Moreover, if a planar surface, instead of a surface with the concave pattern, is used, the technical trouble in the conventional micro contact printing technology can be avoided. As shown in FIG. 2D, the semiconductor devices 20 are moved so that the batch of selected array-type micro semiconductor structures 24 can be remained on the adhesive material 30 after the native substrate 22 is removed. In addition, there are still some unselected micro semiconductor structures 24 remained on the native substrate 22. These unselected array-type micro semiconductor structures 24 will be departed from the adhesive material 30 along with the native substrate 22.

Referring to FIGS. 2E to 2H, the step S40 is to provide an attaching device 40 for transferring the batch of the selected array-type micro semiconductor structures 24 to the target substrate 50. In this embodiment, the attaching device 40 has a planar and uniform attaching surface 42. As shown in FIG. 2E, the attaching device 40 is an attaching plane, and the attaching surface 42 is formed on the attaching plane. The attaching plane moves toward the adhesive material 30 along a direction perpendicular to the adhesive material 30 for attaching the batch of selected array-type micro semiconductor structures 24. As shown in FIG. 2F, a UV light is provided to irradiate and cure the adhesive material 30, which is made of a UV tape, thereby decreasing the adhesion between the adhesive material 30 and the batch of selected array-type micro semiconductor structures 24. As shown in FIG. 2G the attaching device 40 carries the batch of selected array-type micro semiconductor structures 24 to depart from the adhesive material 30 along the direction perpendicular to the adhesive material 30. As shown in FIG. 2H, the attaching device 40 transfers the batch of selected array-type micro semiconductor structures 24 to the target substrate 50. In general, the target substrate 50 at least includes a thin-film substrate 52 and a plurality of conductive portions 54 disposed on the thin-film substrate 52. The conductive portions 54 can include metal electrodes, which is pre-fusible and is attachable. Moreover, the conductive portions 54 may further include solders or similar attaching materials preset on the metal electrodes. To be noted, the above description of the conductive portions 54 is for an example and is not for limiting the scope of the disclosure. Referring to FIG. 21, the conductive portions 54 of the target substrate 50 are contacted and adhered to the electrodes 244 of the batch of selected array-type micro semiconductor structures 24, and the attaching device 40 is removed when or after the batch of selected array-type micro semiconductor structures 24 are positioned on the target substrate 50.

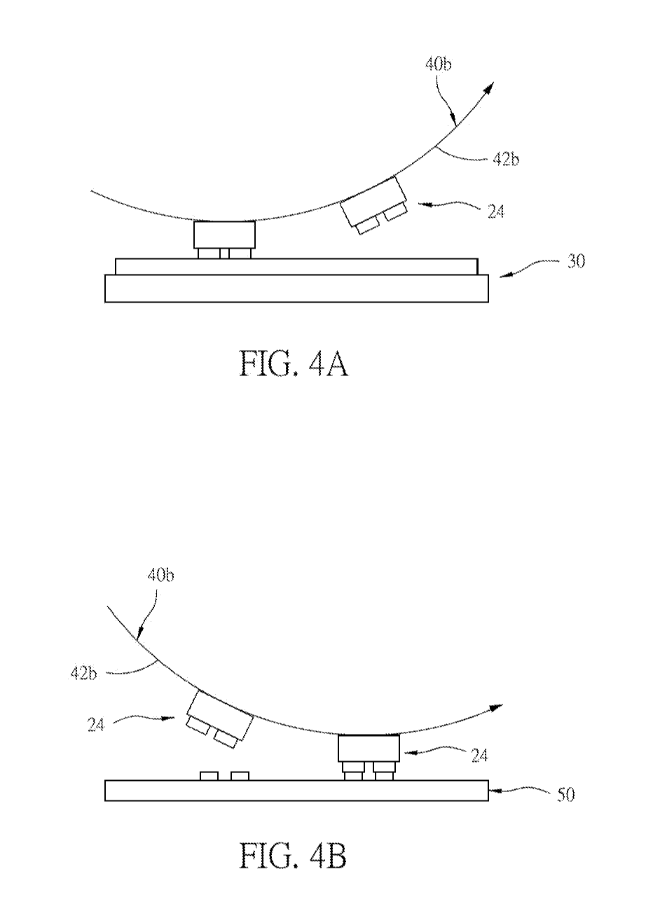

In another embodiment, as shown in FIGS. 4A to 4B, the attaching device includes at least one attaching roller 40b, and an attaching surface 42b is formed on the attaching roller 40b. The attaching roller 40b can transfer and position the batch of selected array-type micro semiconductor structures 24 on the target substrate 50.

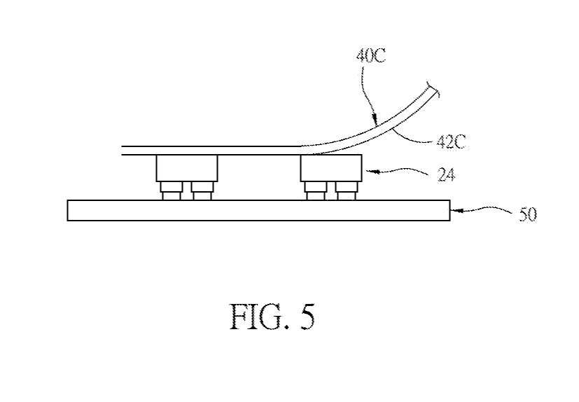

As shown in FIG. 5A, the attaching device is still an attaching plane 40c, and the attaching surface 42c is formed on the attaching plane 40c. The attaching plane 40c can transfer and position the batch of selected array-type micro semiconductor structures 24 on the target substrate 50. Then, the attaching plane 40c is torn off by an angle. Similarly, the attaching plane 40c can attach (pick up) the batch of selected array-type micro semiconductor structures 24 by an angle.

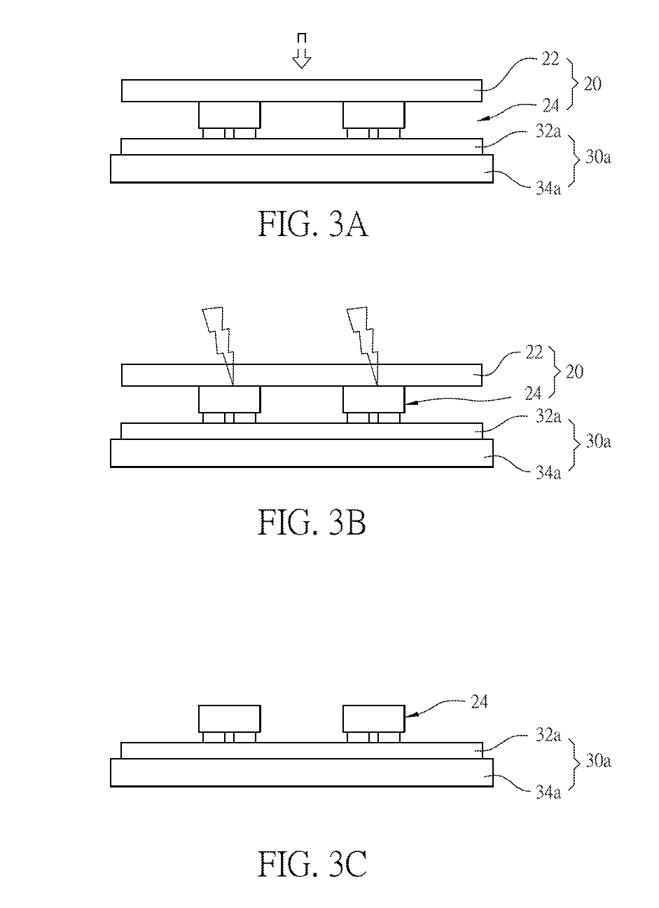

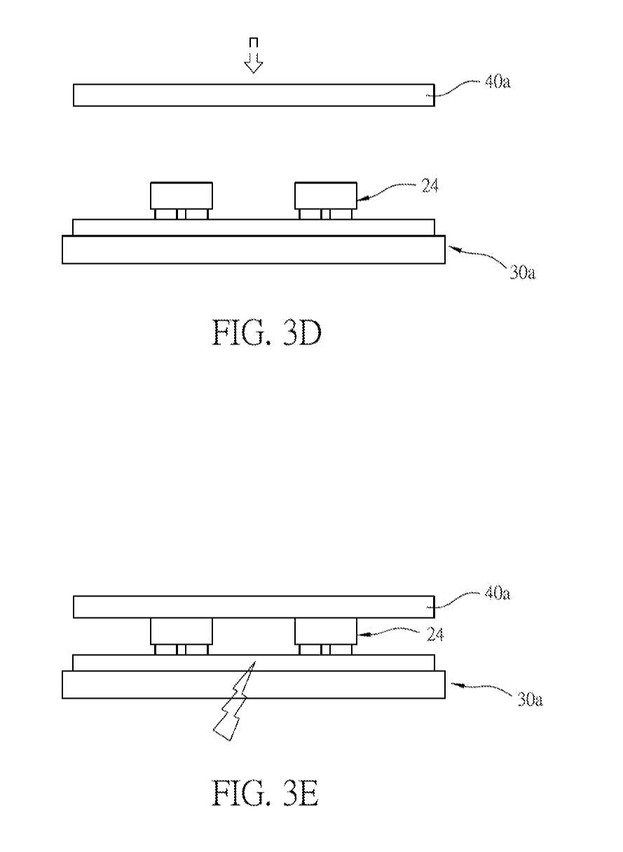

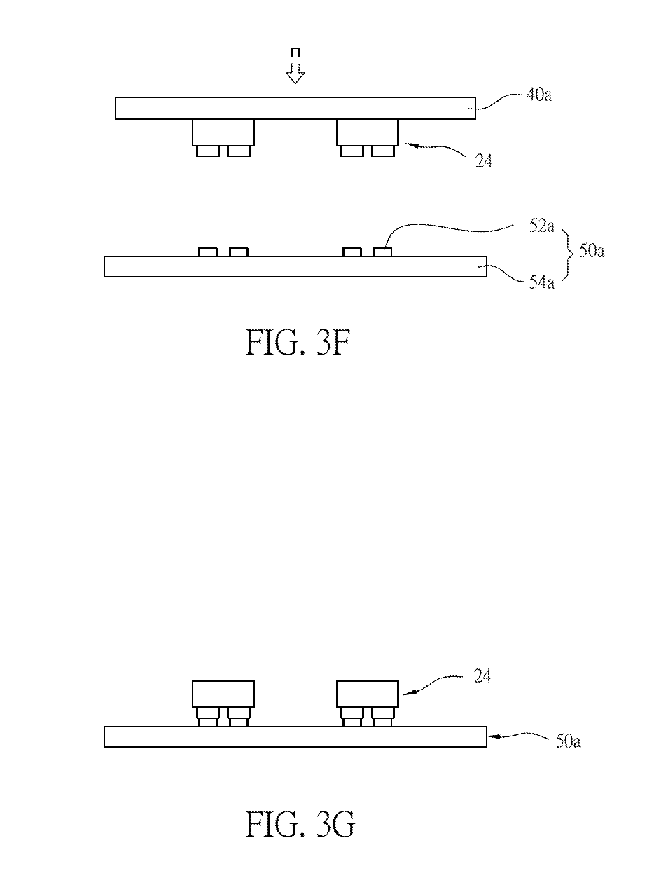

With reference to FIGS. 1A and 3A to 3G; the semiconductor device 20 containing the remained unselected micro semiconductor structures 24 can go through the steps S20, S30 and S40 again.

Referring to FIG. 3A, in the semiconductor device 20, the step S20 is performed to selectively lift a part or all of the remained array-type micro semiconductor structures 24 off the native substrate 22.

Referring to FIG. 3B, in the step S30, the selectively lift-off pattern can be corresponding to the same target substrate 50 or another target substrate. If all of the remained unselected micro semiconductor structures 24 are lifted off, the native substrate 22 can be completely removed individually (see FIG. 3C).

Referring to FIGS. 3D to 3G the step S40 is to provide an attaching device for transferring the batch of the array-type micro semiconductor structures 24 to the target substrate. Herein, the provided attaching device can be the same attaching device 40 used in the previous step S40 or another attaching device 40a. The target substrate can be the same target substrate 50 as shown in FIGS. 2H and 21, or another target substrate 50a. Similar to the above-mentioned target substrate 50, the target substrate 50a also includes a thin-film substrate 52a and a plurality of conductive portions 54a disposed on the thin-film substrate 52a. The attaching device 40a also has a planar and uniform attaching surface 42a. As shown in FIG. 3D, the attaching device 40a attaches the array-type micro semiconductor structures 24 remained on the adhesive material 30. As shown in FIG. 3E, a UV light is provided to irradiate and cure the adhesive material 30, thereby decreasing the adhesion between the adhesive material 30 and the array-type micro semiconductor structures 24. As shown in FIG. 3F, the attaching device 40a carries the batch of selected remained array-type micro semiconductor structures 24 to depart from the adhesive material 30. As shown in FIG. 3G, the attaching device 40a transfers the batch of selected remained array-type micro semiconductor structures 24 to the target substrate 50a, and then the attaching device 40a is removed.

### Second Embodiment

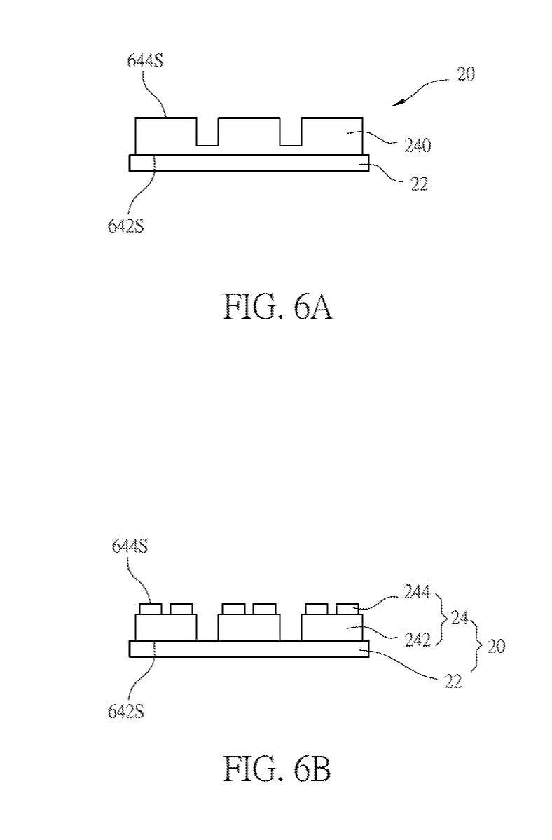

FIGS. 1B and 6A to 6B are schematic diagrams showing the details of FIG. 1A, and the steps and components having similar instructions and functions have the same reference numbers.

In this embodiment, before the step S20, the step S10 is to prepare the semiconductor device 20.

The step S10 at least includes two steps S12 and S14. The step S12 is to provide a native substrate 22 grown with a structural layer 240 (see FIG. 6A), and the step S14 is to perform a following manufacturing process with the structural layer 240 to form a plurality of micro semiconductor structures 24 in an array on the native substrate 22 (see FIG. 6B). The steps of preparing the structural layer 240 and forming a plurality of micro semiconductor structures 24 may not be continuous steps. In other words, the steps S12 and S14 can be not consequent steps, and an additional step or additional steps can be performed between the steps S12 and S14. The structural layer 240 and the array-type micro semiconductor structures 24 have the same first surface 242s and the same second surface 244s. The first surface 242s of the array-type micro semiconductor structures 24 is defined by the micro semiconductor semi-structures 242, and the first surface 242s of the array-type micro semiconductor structures 24 is attached to the native substrate 22. The second surface 244s of the array-type micro semiconductor structures 24 is opposite to the first surface 242s and defined by the electrodes 244.

### Third Embodiment

FIGS. 1C, 7A, 7B and 8A to 8D show a third embodiment of this disclosure, wherein the electrodes of the micro semiconductor structures are different. To make this embodiment be more easily understood, the electrodes of the micro semiconductor structures are vertical electrodes for example. The steps referring to similar indications and functions of the second embodiment will use the same reference numbers.

The step S10 at least includes the steps S12, S14 and S16.

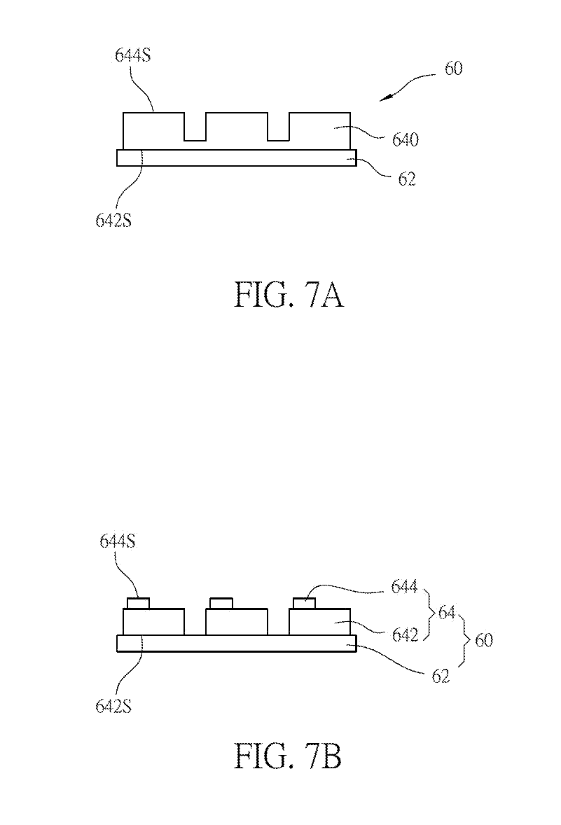

The step S12 is to provide a native substrate 62 grown with a structural layer 640 (see FIG. 7A).

The step S14 is to perform a following manufacturing process with the structural layer 640 to form a plurality of micro semiconductor structures 64 in an array on the native substrate 62. In this embodiment, each of the array-type micro semiconductor structures 64 comprises a single electrode 644 only (either an upper electrode or a lower electrode). The first surface 642s of the array-type micro semiconductor structures 64 is defined by the micro semiconductor semi-structures 642, and the first surface 642s of the array-type micro semiconductor structures 64 is attached to the native substrate 62. The second surface 644s of the array-type micro semiconductor structures 64 is opposite to the first surface 642s and defined by the electrodes 644 (see FIG. 7B).

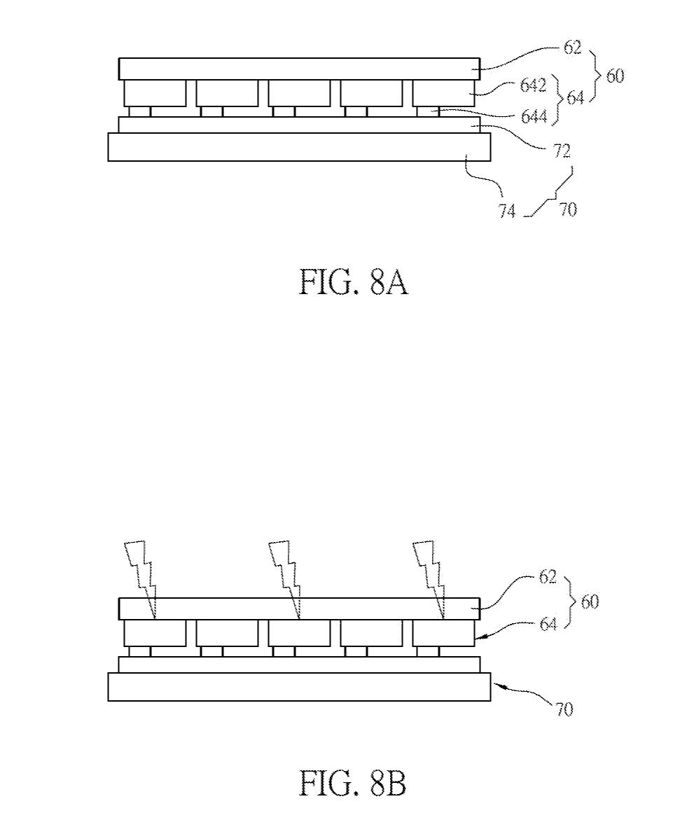

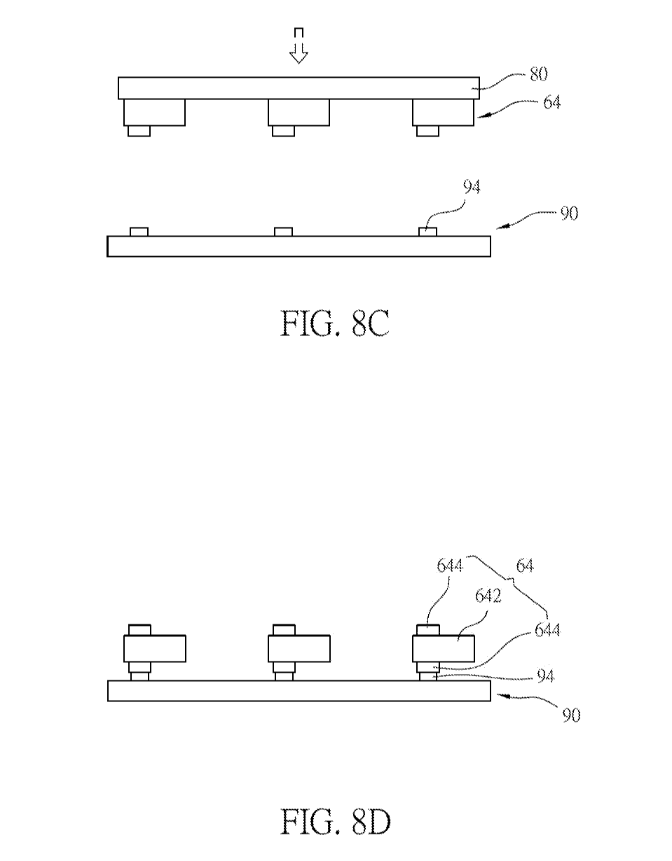

In the step S20, one end of the micro semiconductor structures 64 configured with the electrodes 644 is attached to the adhesive material 70 (see FIG. 8A) so as to selectively lift off a batch of selected array-type micro semiconductor structures 64 (see FIG. 8B).

After the step S40, the batch of the array-type micro semiconductor structures 64 are transferred to a target substrate 90. The target substrate 90 is configured with a plurality of conductive portions 94, and the single electrode 644 of each micro semiconductor structure 64 is connected with the conductive portion 94 of the target substrate 90 (see FIG. 8C).

The step S16 is to prepare another electrode 644 on the batch of the array-type micro semiconductor structures 64 (see FIG. 8D).

In this disclosure, the term “batch transferring” (transfer a batch of micro semiconductor structures) is to select and transfer at least a part of at least one row of the micro semiconductor structures 24 or 64. In some embodiments, to transfer a batch of micro semiconductor structures can be to select and transfer a plurality of rows of micro semiconductor structures 24 or 64, to select and transfer a part of a row of micro semiconductor structures 24 or 64, to select and transfer a part of a plurality of rows of micro semiconductor structures 24 or 64, or any combination of the above. Similarly, the term “batch transferring” is usually determined by the design requirement of the target substrate 50 or 50a. These examples are for illustrations only and not to limit the explanation of the term “batch transferring”.

The above-described embodiments and their processing flows may all be disassembled, misplaced, replaced, or mixed, and implemented together with permission of process conditions.

Therefore, the present disclosure can be implemented by any combination, under the permission of process conditions, according to the concept of replacing the main steps, disassembling/substituting sub-steps, or adjusting the implementation order of at least one sub-step in another main step.

Accordingly, the method of batch transferring micro semiconductor structures of this disclosure can efficiently and effectively select and pick up the micro semiconductor structures 24 or 64 (micro-scaled structures/devices) in batch or in a huge amount and integrate them on to the target substrate 50, 50a or 90 (non-native substrate). This method can be applied to different micro LED dies, devices or semi-products, and can be further widely used to transfer various micro semiconductor structures in batch or in a huge amount.

As mentioned above, the method of batch transferring micro semiconductor structures of this disclosure includes, for example but not limited to, the following functions.

1. The batch selecting event happens in the laser lift-off step, so whether the concave pattern is formed on the attaching device in advance or not does not affect the following batch transferring step. Therefore, the manufacturing process becomes more flexible.

2. The batch selecting event happens in the laser lift-off step, so it is unnecessary to form the concave pattern on the attaching device in advance, which can avoid the technical difficult derived by the micro-contact printing process.

3. The method can be used to select and transfer the ultra-thin, fragile and/or small devices without causing the damage of the devices.

4. The method can efficiently and effectively transfer the micro semiconductor structures in batch or in a huge amount on to the target substrate.

5. The method can reduce the assembling cost and increase the production yield, so it can be widely applied to transfer the micro semiconductor structures in batch or in a huge amount.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. A method of batch transferring micro semiconductor structures, comprising:
attaching an adhesive material on a semiconductor device, wherein the semiconductor device comprises a native substrate and array-type micro semiconductor structures grown on the native substrate, and the array-type micro semiconductor structures define a plurality of micro semiconductor structures arranged in an array;
selectively lifting a part of the array-type micro semiconductor structures off the native substrate, so that a batch of the selected array-type semiconductor structures is remained on the adhesive material after the native substrate is removed; and
providing an attaching device for transferring the batch of the selected array-type micro semiconductor structures to a target substrate.

2. The method according to claim 1, after or in the step of selectively lifting the part of the array-type micro semiconductor structures off the native substrate, further comprising:
removing the unselected array-type semiconductor structures from the attaching material along with the native substrate.

3. The method according to claim 1, wherein the step of selectively lifting the part of the array-type micro semiconductor structures off the native substrate comprises:
selectively lifting the part of the array-type micro semiconductor structures off the native substrate by laser lift-off technology.

4. The method according to claim 1, wherein the attaching device has a planar and uniform attaching surface.

5. The method according to claim 4, wherein the attaching device comprises an attaching plane, and the attaching surface is formed on the attaching plane.

6. The method according to claim 4, wherein the attaching device comprises at least an attaching roller, and the attaching surface is formed on the attaching roller.

7. The method according to claim 3, wherein the attaching device has a planar and uniform attaching surface.

8. The method according to claim 7, wherein the attaching device comprises an attaching plane, and the attaching surface is formed on the attaching plane.

9. The method according to claim 7, wherein the attaching device comprises at least an attaching roller, and the attaching surface is formed on the attaching roller.

10. The method according to claim 1, before the step of attaching the adhesive material on the semiconductor device, further comprising:
growing the array-type micro semiconductor structures on the native substrate, wherein the grown array-type micro semiconductor structures are a plurality of defined micro semiconductor structures, each of which comprises at least an epitaxial layer.

11. The method according to claim 1, wherein the batch of the array-type micro semiconductor structures on the target substrate are horizontal-electrode micro light-emitting diode dies.

12. The method according to claim 1, wherein the batch of the array-type micro semiconductor structures on the target substrate are vertical-electrode micro light-emitting diode dies.
